(19) United States
(12) Patent Application Publication
(10) Pub. No.: US 2008/0186647 A1
(43) Pub. Date: Aug. 7, 2008

(54) ELECTROSTATIC CHUCK AND METHOD OF MANUFACTURING THE SAME

(75) Inventors: Tetsuya KAWAJIRI, Handa-Shi (JP); Kazuhiro Nobori, Nagoya-Shi (JP)

Correspondence Address: BURR & BROWN, PO BOX 7068, SYRACUSE, NY, 13261-7068, US

(73) Assignee: NGK Insulators, Ltd., Nagoya-Shi (JP)

(21) Appl. No.: 12/018,970

(22) Filed: Jan. 24, 2008

(30) Foreign Application Priority Data
Feb. 7, 2007 (JP) 2007-027935

(51) Int. Cl. H01L 21/683; B05D 1/00

(52) U.S. Cl. 361/234; 427/180

(57) ABSTRACT

An electrostatic chuck includes an ESC electrode E1 that is disc-shaped in plan view, an ESC electrode E2 that is doughnut-shaped in plan view, and a dielectric layer formed to cover surfaces of the ESC electrodes E1 and E2. The dielectric layer includes a disc-shaped dielectric region R1 formed in an area corresponding to the surface of the ESC electrode E1, and a doughnut-shaped dielectric region R2 formed in an area corresponding to the surface of the ESC electrode E2, and these two dielectric regions R1 and R2 are sintered seamlessly into an integrated form. The dielectric regions R1 and R2 are formed using different materials having different volume resistivities with the same kind of sintering additives. To each of the ESC electrodes E1 and E2, a terminal for voltage application is connected so that voltage can be applied individually to the ESC electrodes E1 and E2.

### CROSS REFERENCE TO RELATED APPLICATION

This application is based upon and claims the benefit of priority from a Japanese Patent Application No. TOKUGAN 2007-27935, filed on Feb. 7, 2007; the entire contents of which are incorporated herein by reference.

### BACKGROUND OF THE INVENTION

1. Field of the Invention

The present invention relates to an electrostatic chuck for fixing a substrate using electrostatic force, and to a method of manufacturing the electrostatic chuck.

2. Description of the Related Art

In a semiconductor manufacturing process or a liquid crystal display manufacturing process, an electrostatic chuck is generally used to fix a substrate, such as a silicon wafer and glass plate. The electrostatic chuck is a device that fixes the substrate using electrostatic attraction (Coulombic force), and has a structure in which a dielectric layer is formed to cover an electrode. When this electrostatic chuck is used to fix the substrate, the substrate is put in place on the dielectric layer, and then voltage is applied to the electrode, which thereby produces coulombic force between the substrate and the electrode, or produces Johnsen-Rahbek force, a sort of electrostatic force, between the substrate and the surface of the dielectric layer. By utilizing these forces, the substrate is fixed onto the dielectric layer.

The volume resistivity of the dielectric layer that is a component of the electrostatic chuck varies depending on temperature. When the volume resistivity of the dielectric layer falls below a certain lower limit due to temperature change, a leakage current from the electrode to the substrate increases, thereby failing to secure insulation between the electrostatic chuck and the substrate. In contrast, when the volume resistivity of the dielectric layer reaches or exceeds a certain upper limit, chucking and dechucking performance is deteriorated. Therefore, in order to make the electrostatic chuck operable in a wide temperature range while the insulation between the electrostatic chuck and the substrate is being secured with the excellent chucking and dechucking performance, the volume resistivity of the dielectric layer needs to be within an appropriate range (10⁹ to 10¹² Ω·cm) in a controlled manner.

Against this background, as disclosed in Japanese Patent Application Laid-Open Publication No. 2005-294648, recent applications have been devised to extend the temperature range where the electrostatic chuck can work, by changing material composition of the dielectric layer to reduce the temperature dependency of the volume resistivity of the dielectric layer.

There is, however, a limit in reducing the temperature dependency of the volume resistivity of the dielectric layer by changing the material composition of the dielectric layer, which leads to a limited temperature range where the electrostatic chuck can work. Therefore, it has been desirable to provide an electrostatic chuck available in a wider temperature range while the insulation between the electrostatic chuck and the substrate is secured with the excellent chucking and dechucking performance.

### SUMMARY OF THE INVENTION

The present invention is proposed to solve the foregoing problem, and an object thereof is to provide an electrostatic chuck available in a wide temperature range while insulation between the electrostatic chuck and a substrate is being secured with excellent chucking and dechucking performance.

In the electrostatic chuck according to the present invention, a dielectric layer has a plurality of dielectric regions with different volume resistivities, and the plurality of dielectric regions are sintered seamlessly into an integrated form with the same kind of sintering additives. Electrostatic chuck terminals are provided for each dielectric region, and voltage application is switched among the electrostatic chuck terminals depending on operating temperature to change a dielectric region used to fix a substrate.

According to the electrostatic chuck in the present invention, the dielectric layer is composed of the plurality of the dielectric regions that are sintered seamlessly into an integrated form with the same kind of sintering additives, and that have different volume resistivities. By switching voltage application among the electrostatic chuck terminals depending on operating temperature, a dielectric region used to fix the substrate is changed. As a result, the electrostatic chuck can be used in a wide temperature range while insulation between the electrostatic chuck and the substrate is being secured with excellent chucking and dechucking performance.

### BRIEF DESCRIPTION OF THE DRAWINGS

Exemplary embodiments of the invention will become more fully apparent from the following description and appended claims, taken in conjunction with the accompanying drawings. Understanding that these drawings depict only exemplary embodiments and are, therefore, not to be considered limiting of the invention's scope, the exemplary embodiments of the invention will be described with additional specificity and detail through use of the accompanying drawings in which:

FIG. 1 is a top view of an electrostatic chuck according to an embodiment of the present invention;

FIG. 2 is a cross section of the electrostatic chuck shown in FIG. 1;

FIGS. 3A-3D show schematic diagrams showing structures of a dielectric layer in application examples thereof according to the embodiment of the present invention;

FIG. 4 is a table showing properties of materials used for the dielectric layer;

FIG. 5 is a diagram showing temperature dependency of volume resistivity of the materials shown in FIG. 4;

FIG. 6 is a schematic diagram showing a structure of a device used for evaluations of leakage current and chucking and dechucking performance of an electrostatic chuck; and

FIG. 7 is a table showing evaluation results of leakage current and chucking and dechucking performance of electrostatic chucks in the examples and comparative examples.

### DETAILED DESCRIPTION OF THE PREFERRED EMBODIMENTS

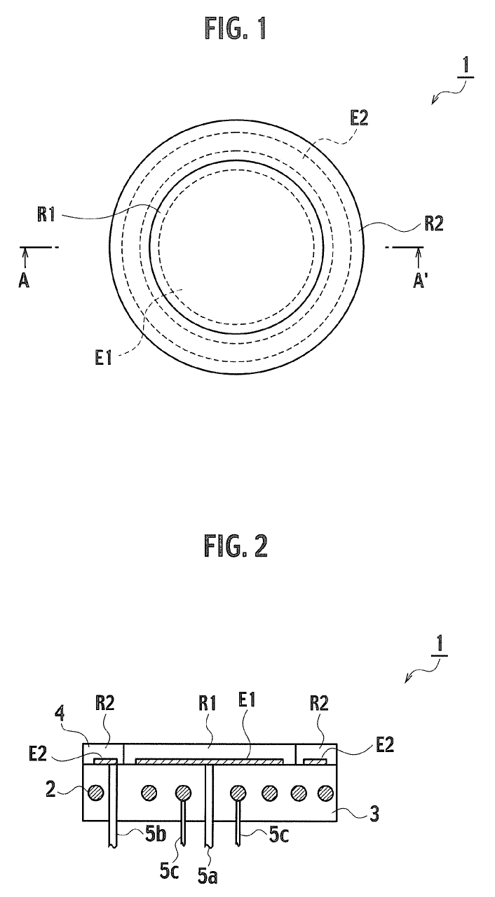

Referring to FIGS. 1 and 2, a structure of an electrostatic chuck will be described according to an embodiment of the present invention. FIG. 1 is a top view of the electrostatic chuck in the embodiment of the present invention, and FIG. 2 is a cross section of the electrostatic chuck along a line AA′ of FIG. 1.

An electrostatic chuck 1 according to the embodiment of the present invention includes a base substrate 3 having a heating resistor 2 buried therein that is spiral-shaped in plan view, an electrostatic chuck electrode (hereinafter, referred to as ESC electrode) E1 that is formed on a surface of the base substrate 3 and is disc-shaped in plan view, an ESC electrode E2 that is formed on the surface of the base substrate 3 so as to enclose the ESC electrode E1 and is doughnut-shaped in plan view, and a dielectric layer 4 formed on the surface of the base substrate 3 to cover the surfaces of the ESC electrodes E1 and E2. The dielectric layer 4 has a round-shaped dielectric region R1 formed in an area corresponding to the surface of the ESC electrode E1, and a doughnut-shaped dielectric region R2 formed in an area corresponding to the surface of the ESC electrode E2. These two regions are sintered seamlessly into an integrated form. The dielectric regions R1 and R2 are made from different volume resistivity material with the same kind of sintering additives (materials that can be sintered in the same sintered condition). To the ESC electrode E1, the ESC electrode E2, and the heating resistor 2, voltage application terminals 5a, 5b, and 5c, respectively, are connected so that voltage can be applied individually to the ESC electrodes E1 and E2, and the heating resistor 2. The heating resistor 2 can have a plurality of fold-back portions arranged concentrically in plan view, and thus any design is applicable.

In general, the volume resistivity of a dielectric layer varies depending on temperature, and therefore a temperature range where an electrostatic chuck works also changes depending on composition of a dielectric layer. For this reason, the electrostatic chuck 1 features switching of voltage application between the ESC electrodes E1 and E2 in accordance with an operating temperature. Specifically, in the following condition, voltage is applied to the ESC electrode E1 via the terminal 5a in the range between temperatures T1 and T2, and also applied to the ESC electrode E2 via the terminal 5b in the range between temperatures T3 and T4. The condition is when the volume resistivity of the dielectric region R1 falls within a range of values where the electrostatic chuck works while insulation between the electrostatic chuck and the substrate is being secured with excellent chucking and dechucking performance in a temperature range between temperatures T1 and T2 (>temperature T1), and at the same time the volume resistivity of the dielectric region R2 falls within a range of values where the electrostatic chuck works while insulation between the electrostatic chuck and the substrate is being secured with excellent chucking and dechucking performance in a temperature range between temperatures T3 (>temperature T2) and T4 (>temperature T3). The range of values of the volume resistivity where the electrostatic chuck works while insulation between the electrostatic chuck and the substrate is being secured with excellent chucking and dechucking performance is 10⁹ to 10¹² Ω·cm, and more preferably, 10^{9.5} to loll Ω·cm. As a consequence, Johnsen-Rahbek force is produced between the surface of the dielectric region on the voltage-applied electrode and the substrate, and this Johnsen-Rahbek force holds the substrate on the dielectric layer 4.

As described above, the ESC electrodes E1 and E2 are formed below the dielectric regions R1 and R2, respectively, having different volume resistivities, and therefore by switching voltage application between the ESC electrodes E1 and E2 depending on operating temperature as described above, the dielectric layer 4 can work as an electrostatic chuck in a wide temperature range while the insulation between the electrostatic chuck and the substrate is being secured with excellent chucking and dechucking performance.

Note that the dielectric regions R1 and R2 have different volume resistivities but are formed using materials with the same kind of sintering additives, and therefore a defect free interface is formed between these two regions, which never causes problems such as cracks from sintering of the dielectric layer 4 and insufficient sintering thereof. Furthermore, the dielectric regions R1 and R2 are sintered seamlessly into an integrated form, and in-plane distribution of the volume resistivity of the dielectric layer 4 is made, which provides excellent thermal uniformity, and prevents degassing from clearance in the interface between two dielectric regions and also emergence of particles from the same, unlike the case where a plurality of dielectric regions having different volume resistivities are formed separately. Moreover, it is able to provide an electrostatic chuck with excellent flatness to satisfactorily achieve uniform contact with the substrate, and with high accuracy of dimension.

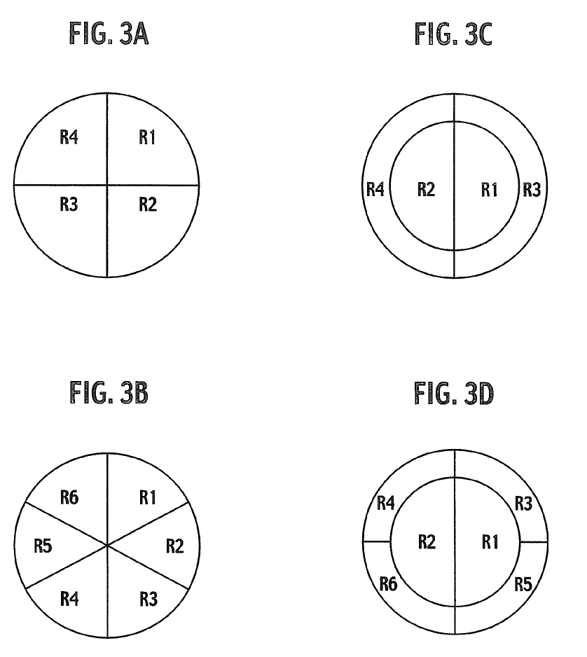

In this embodiment, the dielectric layer 4 is composed of two dielectric regions of the round-shaped dielectric region R1 and the doughnut-shaped dielectric region R2 formed to enclose the dielectric regions R1, and the present invention is, however, not limited to this embodiment. The number, size, and layout of dielectric regions are changeable as necessary depending on the number, size, and layout of the ESC electrodes, and on a desired operating temperature range. Specifically, as shown in FIGS. 3A and 3B, a plurality of dielectric regions with different volume resistivities can be formed in a circumferential direction, and also as shown in FIGS. 3C and 3D, the dielectric regions R1 and R2 in this embodiment can be further subdivided into a plurality of dielectric regions. In this case, it would be desirable to place different dielectric regions in a ring-like or symmetrical manner, in terms of chucking balance of the substrate to the dielectric layer 4.

Note that in the example of FIG. 3A, voltage application is switched between a pair of ESC electrodes below the dielectric regions R1 and R3 and a pair of ESC electrodes below the dielectric regions R2 and R4. In the example of FIG. 3B, voltage application is switched among a pair of ESC electrodes below the dielectric regions R1 and R4, a pair of ESC electrodes below the dielectric regions R2 and R5, and a pair of ESC electrodes below the dielectric regions R3 and R6.

In addition, in the example of FIG. 3C, voltage application is switched between a pair of ESC electrodes below the dielectric regions R1 and R2 and a pair of ESC electrodes below the dielectric regions R3 and R4. In the example of FIG. 3D, voltage application is switched among a pair of ESC electrodes below the dielectric regions R1 and R2, a pair of ESC electrodes below the dielectric regions R3 and R6, and a pair of ESC electrodes below the dielectric regions R4 and R5.

### EXAMPLES

A method of manufacturing the electrostatic chuck 1 and the dielectric layer 4 will be described in detail below by way of examples.

### (Method of Manufacturing Electrostatic Chuck)

A manufacturing process of the electrostatic chuck 1 mainly includes (1) mixing of material powders, (2) forming, (3) sintering, and (4) machining. In the mixing process (1) of material powders, aluminum nitride material powder, samarium oxide or europium oxide, and other additives, are blended in a predetermined ratio and mixed together using a trommel and the like. Mixing can be done either by a wet method or a dry method, and when the wet method is employed, drying is performed by using an SD (spray dryer) and the like after mixing, thereby to obtain material mixture powder. An aluminum nitride material can be prepared according to various preparing methods, such as direct nitriding, reduction and nitridation, and vapor phase synthesis. The aluminum nitride material powder having a high purity of 99.8 wt % or above, and more preferably, 99.9 wt % or above, is used. In order to prevent color shading of a product and obtain fine appearance thereof, a black colorant can be added. The black colorant includes metals of transition metal elements such as Ti, Zr, and Cr, as well as metallic compounds such as metallic oxide, nitride, carbide, sulfate, nitrate, and organometallic compound.

In the forming process (2), the material mixture powder containing the aluminum nitride material powder obtained in the mixing process (1) is used as it is, or a material granulated by adding binder to the material mixture powder is used. A method of forming is not limited, and various methods are applicable, which include, for example, Uniaxial pressing, CIP (Cold Isostatic Pressing), and slip casting. It would be preferable to bury the heating resistor 2 and the ESC electrodes E1 and E2 in this forming process. Specifically, the material mixture powder is added in a metal mold, the heating resistor 2 is then placed thereon, the material mixture powder is further added, the ESC electrodes E1 and E2 are then placed thereon, and the material mixture powder is still further added, thereby completing an integrally formed piece.

In the sintering process (3), there is no restriction on sintering methods, but it would be preferable to employ a hot-press sintering method. The integrally formed piece obtained is placed in a graphite mold for sintering, and then sintered under a pressure of 200 kgf/cm² (1.96×107 Pa) at maximum sintering temperatures from 1,680° C. to 1,900° C. A sintering atmosphere is maintained under vacuum from room temperature up to 1,000° C., and is gaseous nitrogen from 1,000° C. to the maximum sintering temperature. Note that, in order to make intragranular resistance of the dielectric layer 4 higher than intergranular resistance thereof, it would be desirable to prevent excessive crystal growth.

In the machining process (4), an aluminum nitride sintered body obtained by the sintering process is machined into a predetermined shape. Furthermore, bores used to extend electrode terminals are formed, and these terminals are brazed. Note that a cylindrical shaft for accommodating these terminals can be connected to the back surface of the base substrate 3 that is made of ceramics with the same kind of sintering additives as that of the dielectric layer 4. According such a manufacturing method, the base substrate 3 and the dielectric layer 4 are sintered integrally and the ESC electrodes E1 and E2 are buried in the material with high resistance against plasma, which make it possible to provide an electrostatic chuck or an electrostatic chuck heater having extremely high reliability and less contamination, and hardly generating particles. Moreover, the base substrate 3 and the dielectric layer 4 have an equivalent thermal expansion coefficient, thus making it possible to provide an electrostatic chuck heater that is never warped or damaged even in a long-sustained heat cycle.

### (Dielectric Materials)

First, materials used to form the dielectric layer 4 will be described by way of an example.

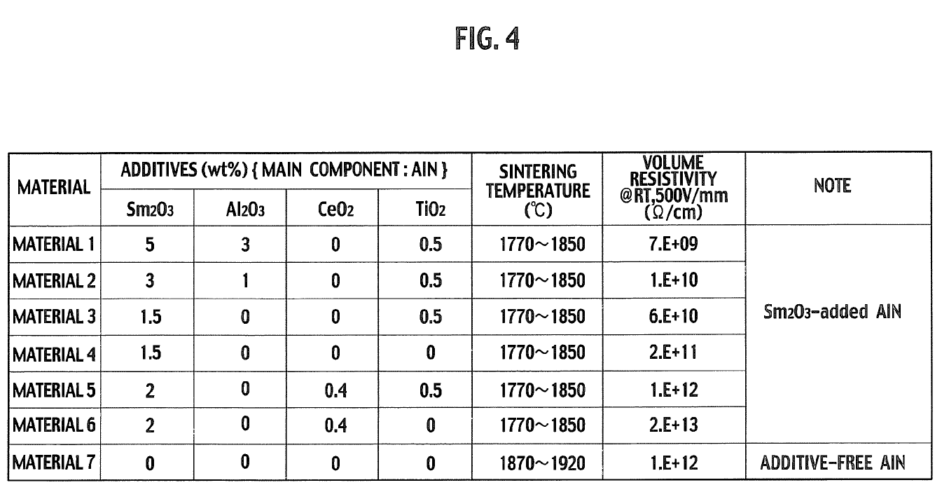

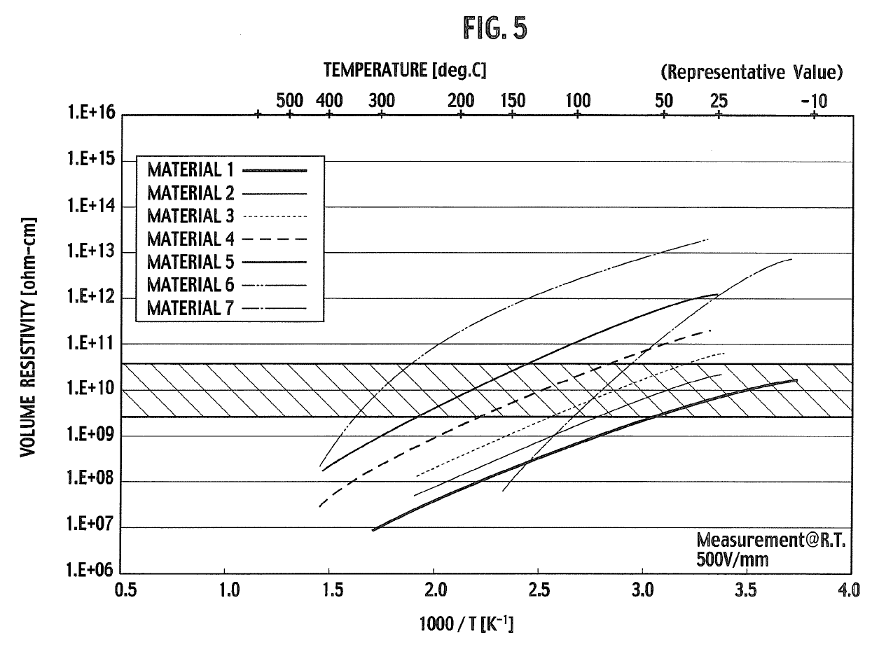

In the example, materials 1 to 7 shown in FIG. 4 are prepared as materials having different volume resistivities with the same kind of sintering additives. As shown in FIG. 4, the materials 1 to 7 mainly contain aluminum nitride (AlN), and also additives used as sintering aids (Sm203, Al₂O₃, CeO₂, TiO₂) at different compounding ratios. These materials 1 to 7 have different temperature dependencies of their respective volume resistivities, and hence have different temperature ranges indicating volume resistivity ranges (diagonally shaded area of FIG. 5) where the dielectric layer can work as the electrostatic chuck while insulation between the electrostatic chuck and the substrate is being secured with excellent chucking and dechucking performance, as shown in FIGS. 4 and 5. Accordingly, by forming the dielectric layer 4 using at least two of the materials 1 to 7 in consideration of the temperature dependency of the volume resistivity of each material, the dielectric layer can work as the electrostatic chuck in a wide temperature range while the insulation between the electrostatic chuck and the substrate is being secured with excellent chucking and dechucking performance.

Note that the volume resistivity of each material shown in FIGS. 4 and 5 was measured according to a method in conformity with JIS_C2141. Specifically, a φ300 mm×5 mm thick sintered body of each material is cut into a sample measuring □5 mm×1 mm thick, and then a main electrode with a diameter of 20 mm and a guard electrode with internal and external diameters of 30 mm and 40 mm, respectively, were formed on each sample surface with Ag paste. Next, on one side of each sample surface, an electrode with a diameter of 40 mm was formed, and the sample was placed in a vacuum atmosphere. Subsequently, a voltage of 500V was applied to the electrode, and a current was read when one minute had passed from the voltage application, thereby to calculate the volume resistivity from room temperature to high temperature.

### (Structure of Dielectric Layer)

Next, description will be given on examples and comparative examples of dielectric layers formed using the foregoing materials 1 to 7.

### Example 1

In an example 1, the dielectric regions R1 and R2 shown in FIGS. 1 and 2 were formed using the materials 1 and 3, respectively, at a sintering temperature of 1,800° C. Subsequently, by forming an ESC electrode below each of the dielectric regions R1 and R2, an electrostatic chuck in the example 1 was prepared.

### Example 2

In an example 2, the dielectric regions R1 and R2 shown in FIGS. 1 and 2 were formed using the materials 1 and 4, respectively, at a sintering temperature of 1,800° C. Subsequently, by forming an ESC electrode below each of the dielectric regions 1 and 2, an electrostatic chuck in the example 2 was prepared.

### Example 3

In an example 3, the dielectric regions R1 and R2 shown in FIGS. 1 and 2 were formed using the materials 5 and 6, respectively, at a sintering temperature of 1,800° C. Subsequently, by forming an ESC electrode below each of the dielectric regions 1 and 2, an electrostatic chuck in the example 3 was prepared.

### Comparative Example 1

In a comparative example 1, a dielectric layer was formed using only the material 1 at a sintering temperature of 1,800° C. Subsequently, by forming an ESC electrode below this dielectric layer, an electrostatic chuck in the comparative example 1 was prepared.

### Comparative Example 2

In a comparative example 2, a dielectric layer was formed using only the material 4 at a sintering temperature of 1,800° C. Subsequently, by forming an ESC electrode below this dielectric layer, an electrostatic chuck in the comparative example 2 was prepared.

### Comparative Example 3

In a comparative example 3, a dielectric layer was formed using only the material 6 at a sintering temperature of 1,800° C. Subsequently, by forming an ESC electrode below this dielectric layer, an electrostatic chuck in the comparative example 3 was prepared.

### Comparative Example 4

In a comparative example 4, a dielectric layer was formed using only the material 7 at a sintering temperature of 1,800° C. Subsequently, by forming an ESC electrode below this dielectric layer, an electrostatic chuck in the comparative example 4 was prepared.

### Comparative Example 5

In a comparative example 5, the dielectric layers R1 and R2 shown in FIGS. 1 and 2 were formed using the materials 1 and 4, respectively, at a sintering temperature of 1,800° C. Subsequently, by forming an ESC electrode across the dielectric regions R1 and R2, an electrostatic chuck in the comparative example 5 was prepared.

### Comparative Example 6

In a comparative example 6, the dielectric regions R1 and R2 shown in FIGS. 1 and 2 were formed using the materials 1 and 7, respectively, at a sintering temperature of 1,800° C. Subsequently, by forming an ESC electrode below each of the dielectric regions R1 and R2, an electrostatic chuck in the comparative example 6 was prepared.

### (Results of Sintering)

In the electrostatic chucks of the examples 1-3 and the comparative examples 1-5, neither cracks from sintering nor insufficient sintering was found in the dielectric layer after sintering had ended. In contrast, in the electrostatic chuck of the comparative example 6, cracks from sintering and insufficient sintering were found in a material-7 region after sintering had ended.

### (Evaluations of Leakage Current and Chucking and Dechucking Performance)

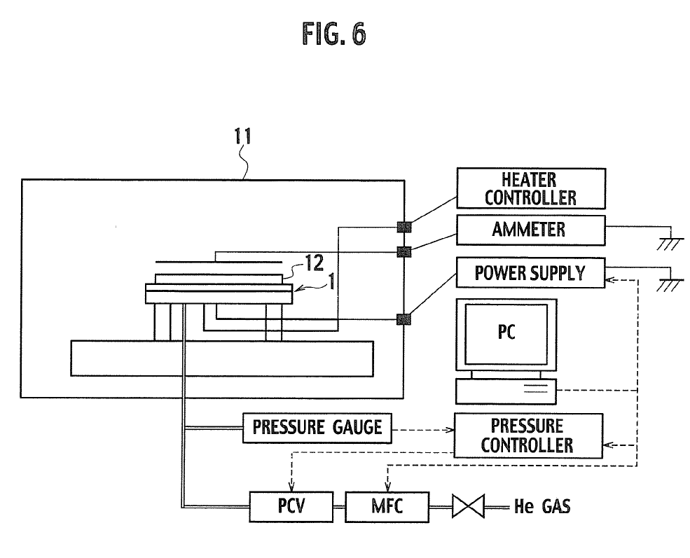

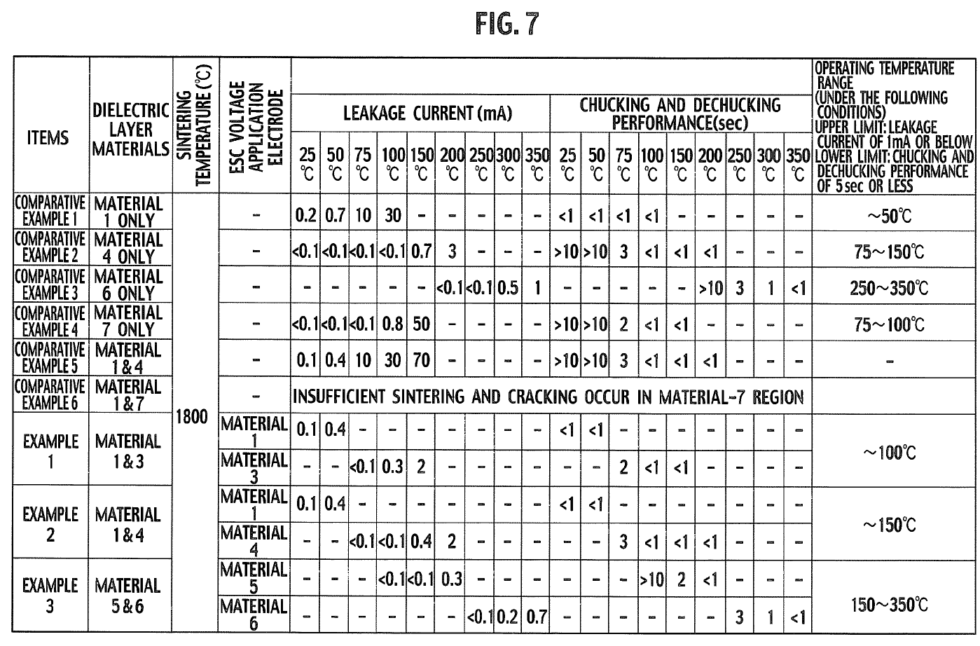

In a chamber 11 shown in FIG. 6, the electrostatic chucks of the examples 1-3 and the comparative examples 1-5 were set individually as the electrostatic chuck 1, and then a substrate 12 was placed on the dielectric layer of the electrostatic chuck 1. After the chamber 11 was evacuated to produce a vacuum atmosphere, a voltage of 500V was applied to the ESC electrode for a minute, whereupon a leakage current was measured. Furthermore, while the voltage was being applied to the ESC electrode, a helium gas was introduced between the substrate and the dielectric layer, and length of time from termination of the voltage application to the ESC electrode until dechucking of the substrate 12 from the dielectric layer was measured in order to evaluate chucking and dechucking performance.

In the electrostatic chuck of the example 1, small leakage currents were observed in a material-1 region in a temperature range from 25° C. to 50° C., and also small leakage currents were observed in a material-3 region in a temperature range from 75° C. to 100° C. Furthermore, excellent chucking and dechucking performance was obtained in the material-1 region in a temperature range from 25° C. to 50° C., and also excellent chucking and dechucking performance was obtained in the material-3 region in a temperature range from 75° C. to 150° C. From these results, the electrostatic chuck of the example 1 was found to work in a temperature range below 100° C.

In the electrostatic chuck of the example 2, a temperature range from 25° C. to 50° C. resulted in small leakage currents in the material-1 region, and also a temperature range from 75° C. to 150° C. resulted in small leakage currents in the material-4 region. Furthermore, a temperature range from 25° C. to 50° C. resulted in excellent chucking and dechucking performance of the material-1 region, and also a temperature range from 75° C. to 200° C. resulted in excellent chucking and dechucking performance of the material-3 region. From these results, the electrostatic chuck of the example 2 was found to work in a temperature range below 150° C.

In the electrostatic chuck of the example 3, a temperature range from 100° C. to 200° C. resulted in small leakage currents in a material-5 region, and also a temperature range from 250° C. to 350° C. resulted in small leakage currents in a material-6 region. Furthermore, a temperature range from 150° C. to 200° C. resulted in excellent chucking and dechucking performance of the material-5 region, and also a temperature range from 250° C. to 350° C. resulted in excellent chucking and dechucking performance of the material-6 region. From these results, the electrostatic chuck of the example 3 was found to work in a temperature range from 150° C. to 350° C.

In the electrostatic chuck of the comparative example 1, a temperature range from 25° C. to 50° C. resulted in small leakage currents, and a temperature range from 25° C. to 100° C. resulted in excellent chucking and dechucking performance. From these results, the electrostatic chuck of the comparative example 1 was found to work in a temperature range below 50° C.

In the electrostatic chuck of the comparative example 2, a temperature range from 25° C. to 150° C. resulted in small leakage currents, and a temperature range from 75° C. to 200° C. resulted in excellent chucking and dechucking performance. From these results, the electrostatic chuck of the comparative example 2 was found to work in a temperature range from 75° C. to 150° C.

In the electrostatic chuck of the comparative example 3, a temperature range from 200° C. to 350° C. resulted in small leakage currents, and a temperature range from 250° C. to 350° C. resulted in excellent chucking and dechucking performance. From these results, the electrostatic chuck of the comparative example 3 was found to work in a temperature range from 250° C. to 350° C.

In the electrostatic chuck of the example 4, a temperature range from 25° C. to 100° C. resulted in small leakage currents, and a temperature range from 75° C. to 150° C. resulted in excellent chucking and dechucking performance. From these results, the electrostatic chuck of the comparative example 4 was found to work in a temperature range from 75° C. to 100° C.

In the electrostatic chuck of the comparative example 5, a temperature range from 25° C. to 50° C. resulted in small leakage currents, and a temperature range from 50° C. to 200° C. resulted in excellent chucking and dechucking performance. From these results, the electrostatic chuck of the comparative example 5 was found not to work.

From these findings, it was confirmed that the electrostatic chucks of the examples 1-3 could be used in a wider temperature range while insulation between those electrostatic chucks and a substrate was being secured with excellent chucking and dechucking performance, as compared to the electrostatic chucks of the comparative examples 1-5.

Although the present invention made by the present inventors has been described in reference to its embodiment, the statement and drawings constituting part of the disclosure of the present invention should not be regarded as limiting the present invention. Various alternative embodiments, examples, and operation techniques made by those skilled in the art on the basis of the foregoing embodiment are, of course, within the scope of the present invention.

What is claimed is:

1. An electrostatic chuck for fixing a substrate using electrostatic force, comprising:
a base substrate;
a dielectric layer being formed on a surface of the base substrate and having a plurality of dielectric regions with different volume resistivities, the plurality of dielectric regions being sintered seamlessly into an integrated form with the same kind of sintering additives; and
electrostatic chuck electrodes buried in the dielectric layer and provided for each dielectric region, wherein
voltage application is switched among the electrostatic chuck electrodes depending on operating temperature to change a dielectric region used to fix the substrate.

2. The electrostatic chuck according to claim 1, wherein
the dielectric layer is formed using aluminum nitride compounded with at least one of Sm oxide, Al oxide, Ce oxide, and Ti oxide, as a sintering aid, and
a compound ratio of the sintering aid is different among the plurality of dielectric regions.

3. The electrostatic chuck according to claim 1, wherein
the dielectric layer has a structure in which the plurality of dielectric regions are disposed symmetrically whose volume resistivities are different but kinds of sintering additives are identical.

4. The electrostatic chuck according to claim 3, wherein the dielectric layer is composed of the plurality of dielectric regions disposed concentrically.

5. The electrostatic chuck according to claim 4, wherein each of the dielectric regions includes a plurality of dielectric regions therein.

6. The electrostatic chuck according to claim 1, wherein the base substrate and the dielectric layer are sintered integrally and seamlessly, and are formed using materials with the same kind of sintering additives.

7. A method of manufacturing the electrostatic chuck according to claim 1, comprising: forming the dielectric layer by sintering under same sintering conditions a plurality of dielectrics whose volume resistivities are different but kinds of sintering additives are identical.
